(19) United States
(12) Patent Application Publication
(10) Pub. No.: US 2012/0060887 A1
(43) Pub. Date: Mar. 15, 2012

(54) ASYMMETRIC THERMOELECTRIC MODULE AND METHOD OF MANUFACTURING THE SAME

(75) Inventors: Yong Suk Kim, Gyunggi-do (KR); Jeong Ho Yoon, Gyunggi-do (KR); Sung Ho Lee, Gyunggi-do (KR); Dong Hyeok Choi, Gyunggi-do (KR); Ji Hye Shim, Gyunggi-do (KR); Kyu Hwan Oh, Gyunggi-do (KR)

(73) Assignee: SAMSUNG ELECTRO-MECHANICS CO., LTD., Gyunggi-do (KR)

(21) Appl. No.: 12/963,185

(22) Filed: Dec. 8, 2010

(30) Foreign Application Priority Data
Sep. 15, 2010 (KR) 1020100090690

(51) Int. Cl. H01L 35/30; H01L 21/04; H01L 35/34

(52) U.S. Cl. 136/224; 438/54; 136/201; 257/E21.04

(57) ABSTRACT

Disclosed is an asymmetric thermoelectric module, which includes a plurality of first-type thermoelectric semiconductor elements, a plurality of second-type thermoelectric semiconductor elements, a plurality of pairs of assistant layers having different melting points and disposed on the upper and lower surfaces of the first-type and second-type thermoelectric semiconductor elements, and a pair of substrates.

### CROSS REFERENCE TO RELATED APPLICATION

This application claims the benefit of Korean Patent Application No. 10-2010-0090690, filed Sep. 15, 2010, entitled “Asymmetry thermoelectric module and manufacturing method thereof”, which is hereby incorporated by reference in its entirety into this application.

### BACKGROUND OF THE INVENTION

1. Technical Field

The present invention relates to an asymmetric thermoelectric module and a method of manufacturing the same.

2. Description of the Related Art

The rapid increase in the use of fossil energy is causing the problems of global warming and energy depletion. In order to solve such problems, the development of thermoelectric modules is actively ongoing these days in every country.

Thermoelectric modules are largely used in a power generation field using the Seebeck effect and a cooling field using the Peltier effect.

In the cooling field, as the size and thickness of electronic components decrease and the power and degree of integration thereof increase in step with the recent advancements being made by the IT industry, the heat value increases. Furthermore, the heat thus generated is regarded as the main cause of faulty operation of electronic instruments and decreased efficiency thereof In order to solve these problems, the use of thermoelectric modules is increasing.

Moreover, taking into consideration the advantages of thermoelectric modules such as noise prevention, a rapid cooling rate, local cooling and environmentally friendly properties, the applications thereof cannot but expand more.

In the power generation field, many attempts have been made to convert much waste heat resulting from automobiles, waste incinerators, ironworks, power generators, earth heat, electronic instruments and body heat into electric energy all over the world. In particular, thermoelectric power generation enables volumetric power generation and is thus able to be combined with other types of power generation, and thereby they are considered to be of wide applicability in the corresponding research field. Furthermore, because global contaminants are not discharged during the production of electric energy, thermoelectric power generation is environmentally friendly and the propagation rate thereof may accelerate in the future.

Typically, a single thermoelectric module mainly includes N-type semiconductor elements, P-type semiconductor elements, electrodes and substrates, and a plurality of such single modules forms a composite module.

In order to obtain the Peltier effect in such a thermoelectric module, electric energy is supplied from the outside so that a difference in temperature at both ends of the thermoelectric module is maintained uniform by movement of electrons and holes.

According to conventional techniques, when current is applied to the thermoelectric module that operates in this way, portions where the metal electrodes and the semiconductor elements are joined to each other may be easily detached due to the difference in temperature at both ends of the thermoelectric module, undesirably deteriorating durability of the thermoelectric module and the electrical, mechanical and thermoelectric properties changing with time.

### SUMMARY OF THE INVENTION

Accordingly, the present invention has been made keeping in mind the problems encountered in the related art and the present invention is intended to provide an asymmetric thermoelectric module, in which assistant layers having different melting points are formed at both sides of a semiconductor element thus improving thermoelectric performance, solving defects due to cracking at contact points, preventing deterioration of the properties with time, and suppressing diffusion of a semiconductor element, and also to provide a method of manufacturing the same.

An aspect of the present invention provides an asymmetric thermoelectric module, comprising a plurality of first-type thermoelectric semiconductor elements having exposed surfaces at upper and lower surfaces thereof, a plurality of second-type thermoelectric semiconductor elements arranged in matrix form so as to be disposed adjacent to the first-type thermoelectric semiconductor elements by predetermined spaces and having exposed surfaces at upper and lower surfaces thereof, a plurality of pairs of assistant layers having different melting points and disposed on the upper and lower surfaces of the first-type thermoelectric semiconductor elements and the second-type thermoelectric semiconductor elements, and a pair of substrates comprising a pair of insulating members and a plurality of electrodes joined in a predetermined pattern to the surface of each of the pair of insulating members and attached to the corresponding assistant layers.

In this aspect, the asymmetric thermoelectric module may comprise a plurality of buffer layers formed on surfaces of the facing electrodes of the substrates and having areas corresponding to the first-type thermoelectric semiconductor elements and the second-type thermoelectric semiconductor elements.

In this aspect, one of the pair of assistant layers may comprise a material having the lowest melting point selected from among thermoelectric materials that form the thermoelectric semiconductor elements, and the other thereof may comprise a material having the highest melting point selected from among thermoelectric materials that form the thermoelectric semiconductor elements.

Another aspect of the present invention provides a method of manufacturing an asymmetric thermoelectric module, comprising (A) joining a plurality of electrodes in a predetermined pattern to a surface of each of a pair of insulating members and forming pairs of assistant layers on the electrodes, thus preparing a pair of substrates, (B) positioning a support having a plurality of holes on one of the pair of substrates, (C) injecting thermoelectric semiconductor powders into the holes of the support, compacting the thermoelectric semiconductor powders, and then separating the support, and (D) positioning the other of the pair of substrates on one of the pair of substrates having the thermoelectric semiconductor powders formed thereon, and then performing thermal treatment so that the thermoelectric semiconductor powders are joined to the pair of substrates.

In this aspect, the method may further comprise (E) forming buffer layers on the electrodes of the pair of substrates, before forming the assistant layers in (A).

In this aspect, (C) may comprise (C-1) injecting the thermoelectric semiconductor powders into the holes of the support, (C-2) compacting the thermoelectric semiconductor powders injected into the holes of the support, and (C-3) separating the support from the substrate.

In this aspect, one of the pair of assistant layers may be an assistant layer comprising Te, and the other thereof may be an assistant layer comprising Bi.

Also in this aspect, one of the pair of assistant layers may comprise at least one selected from among Co, Mo and W, and the other thereof may comprise at least one selected from among Ti, Cr, Mn and Fe.

In this aspect, the thickness of each of the pair of assistant layers may be 1/10˜1/100 of the thickness of the thermoelectric semiconductor elements.

In this aspect, the thermoelectric semiconductor elements may comprise thermoelectric semiconductor powders and low-melting-point metal powders, mixed in a predetermined ratio.

### BRIEF DESCRIPTION OF THE DRAWINGS

The features and advantages of the present invention will be more clearly understood from the following detailed description taken in conjunction with the accompanying drawings, in which:

FIG. 1 is a perspective view showing an asymmetric thermoelectric module according to an embodiment of the present invention;

FIG. 2 is a schematic cross-sectional view showing the asymmetric thermoelectric module according to the embodiment of the present invention; and

FIGS. 3 to 9 are perspective views showing a process of manufacturing the asymmetric thermoelectric module according to the embodiment of the present invention.

### DESCRIPTION OF SPECIFIC EMBODIMENTS

Hereinafter, embodiments of the present invention will be described in detail while referring to the accompanying drawings. Throughout the drawings, the same reference numerals are used to refer to the same or similar elements. Moreover, descriptions of known techniques, even if they are pertinent to the present invention, are regarded as unnecessary and may be omitted when they would make the characteristics of the invention and the description unclear.

Furthermore, the terms and words used in the present specification and claims should not be interpreted as being limited to typical meanings or dictionary definitions, but should be interpreted as having meanings and concepts relevant to the technical scope of the present invention based on the rule according to which an inventor can appropriately define the concept implied by the term to best describe the method he or she knows for carrying out the invention.

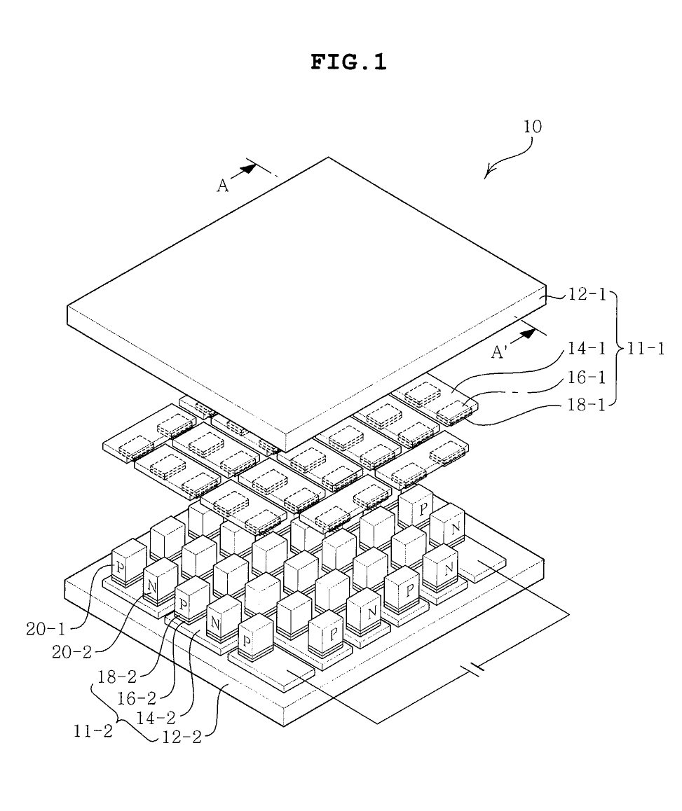

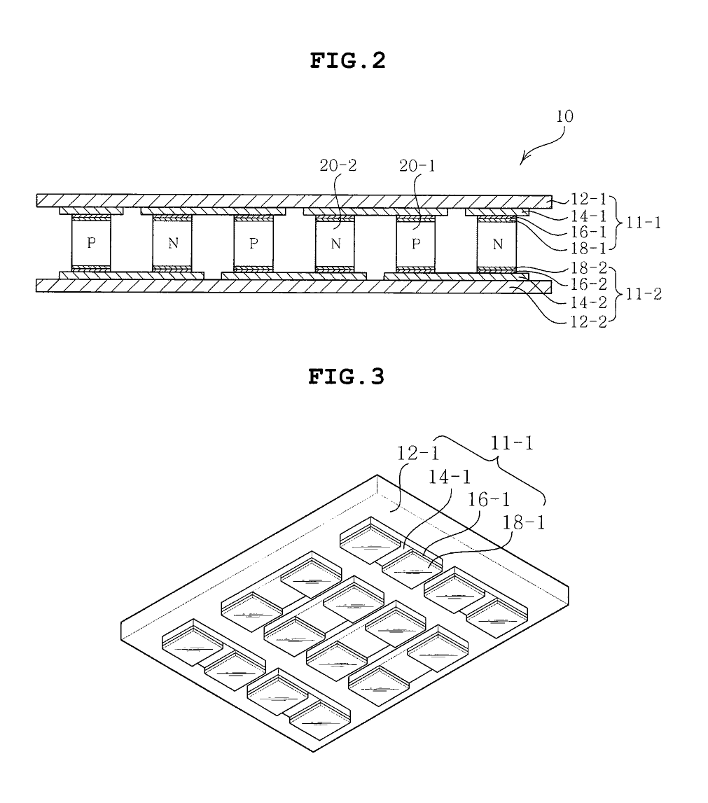

FIG. 1 is a perspective view showing an asymmetric thermoelectric module according to an embodiment of the present invention, and FIG. 2 is a schematic cross-sectional view showing the asymmetric thermoelectric module according to the embodiment of the present invention.

With reference to the drawings, the asymmetric thermoelectric module 10 according to the embodiment of the present invention includes a pair of substrates 11-1, 11-2 including a pair of insulating members 12-1, 12-2 and a plurality of electrodes 14-1, 14-2 joined in a predetermined pattern to the surface of each of the pair of insulating members, buffer layers 16-1, 16-2 formed on the surfaces of the facing electrodes 14-1, 14-2 of the substrates 11-1, 11-2 and having areas corresponding to P-type and N-type semiconductor elements 20-1, 20-2, assistant layers 18-1, 18-2 formed on the surfaces of the facing electrodes 14-1, 14-2 or buffer layers 16-1, 16-2 of the substrates 11-1, 11-2 and having areas corresponding to the P-type and N-type semiconductor elements 20-1, 20-2, and the P-type and N-type semiconductor elements 20-1, 20-2 in contact with the assistant layers 18-1, 18-2 and having a fixed shape due to melting at a predetermined temperature.

The substrates 11-1, 11-2 include plate type insulating members 12-1, 12-2 made of aluminum oxide or the like, and the plurality of electrodes 14-1, 14-2 joined in a predetermined pattern to one surface of each of the insulating members 12-1, 12-2 and made of Cu or the like.

As such, the size and shape of the individual electrodes 14-1, 14-2 may be sufficient so that they can come into contact with respective ends of the P-type semiconductor element 20-1 and the N-type semiconductor element 20-2, which are adjacent to each other.

The buffer layers 16-1, 16-2, which may be selectively used in the present embodiment, may be formed on the electrodes 14-1, 14-2 made of Cu using plating (nickel), thus preventing diffusion of the semiconductor elements 20-1, 20-2 into the corresponding electrodes 14-1, 14-2. In the present embodiment, in the case where the buffer layers 16-1, 16-2 are omitted, the electrodes 14-1, 14-2 may come into direct contact with the assistant layers 18-1, 18-2 corresponding thereto.

The assistant layers 18-1, 18-2 are formed of materials having different melting points. Specifically, the assistant layer 18-1 adjacent to the substrate 11-1 is formed of a material having a high melting point selected from among thermoelectric material powders 21-1, 21-2 that form the semiconductor elements 20-1, 20-2, whereas the assistant layer 18-2 adjacent to the substrate 11-2 is formed of a material having a low melting point selected from among the thermoelectric material powders 21-1, 21-2 that form the semiconductor elements 20-1, 20-2.

For example, in the case where the thermoelectric material powders of the semiconductor elements 20-1, 20-2 are a Bi—Te based material as described below, a Te assistant layer 18-1 having a melting point of 450° C. may be used as the assistant layer 18-1 adjacent to the substrate 11-1, whereas a Bi assistant layer 18-2 having a melting point of 271° C. may be used as the assistant layer 18-2 adjacent to the substrate 11-2.

Furthermore, the Te assistant layer 18-1 may include Co having a melting point of 420° C. which is similar to that of the Te assistant layer, and the Bi assistant layer 18-2 may include Ti having a melting point of 303.5° C. which is similar to that of the Bi assistant layer. Also, the Te assistant layer 18-1 may include Mo or W, in addition to Co, and the Bi assistant layer 18-2 may include Cr, Mn or Fe, in addition to Ti.

The thickness of the assistant layers 18-1, 18-2 may be 1/10˜1/100 of the thickness of the thermoelectric devices 20-1, 20-2.

When the assistant layers 18-1, 18-2 having different melting points are formed in this way, a temperature gradient gradually forms from the edges of the semiconductor elements 20-1, 20-2 upon application of voltage to the thermoelectric module 10, so that phonons which importantly affect thermal conductivity do not scatter but easily move, thereby improving thermoelectric performance.

Also when the assistant layers 18-1, 18-2 having different melting points are formed in this way, coefficients of thermal expansion do not drastically change but stepwisely gradually decrease in the range from the edges of the semiconductor elements 20-1, 20-2 to the electrodes 14-1, 14-2, so that rapid volume expansion does not occur at the edges of the semiconductor elements 20-1, 20-2 upon application of voltage to the thermoelectric module 10, thus minimizing thermal expansion impact to thereby prevent cracking or the like.

When such assistant layers 18-1, 18-2 are used, corrosion resistance may be ensured upon operation in an acid/base atmosphere, and thus deterioration due to changes in electrical conductivity and heat resistance with time may be reduced.

Also when such assistant layers 18-1, 18-2 are used, the semiconductor elements 20-1, 20-2 may be prevented from diffusing into the corresponding electrodes 14-1, 14-2.

The P-type and N-type semiconductor elements 20-1, 20-2 are made of thermoelectric material powders 21-1, 21-2 and low-melting-point metal powders 22-1, 22-2, which are mixed in a predetermined ratio.

The thermoelectric material powders 21-1, 21-2 may include those known in the art, and examples thereof include thermoelectric semiconductors such as a Bi—Te based material, a Fe—Si based material, a Si—Ge based material, a Co—Sb based material, etc. Particularly useful is a Bi—Te based material.

The low-melting-point metal powders 22-1, 22-2 may include metal powders having a comparatively lower melting point than the melting point (e.g. Te (450° C.)) of the thermoelectric material, and examples thereof include Bi (melting point: 271° C.), Tl (melting point: 303.5° C.), Sn (melting point: 232° C.), P (melting point: 44° C.), Pb (melting point: 327° C.), and Cd (melting point: 321° C.).

The semiconductor elements 20-1, 20-2 may be prepared by mixing the thermoelectric material powders 21-1, 21-2 with 0.25˜10 wt % of low-melting-point metal powders 22-1, 22-2. Also, a semiconductor element 20 may be manufactured by injecting materials thereof into holes 32-1, 32-2 of a jig shaped support 30 which will be described later, and then performing thermal treatment at a temperature which is higher than the melting point of the low-melting-point metal powders 22-1, 22-2 and is lower than the melting point of the thermoelectric material powders 21-1, 21-2, so that the low-melting-point metal powders 22-1, 22-2 are melted and thus the semiconductor elements 20-1, 20-2 are produced and simultaneously both ends thereof are joined to the assistant layers 18-1, 18-2.

The semiconductor elements 20-1, 20-2 are arranged in matrix form such that the P-type semiconductor elements 20-1 are disposed adjacent to the N-type semiconductor elements 20-2 by desired spaces in the X and Y directions.

In the thermoelectric module 10 thus configured, when direct-current voltage is applied to the electrodes 14-1, 14-2 and the semiconductor elements 20-1, 20-2 are thus electrically connected to each other, the Peltier effect occurs, so that heat is generated at portions where current flows from the P-type semiconductor elements 20-1 to the N-type semiconductor elements 20-2 whereas heat is absorbed at portions where current flows from the N-type semiconductor elements 20-2 to the P-type semiconductor elements 20-1.

Hence, the insulating member 12-1 joined at portions where heat is generated is heated, and the insulating member 12-2 joined at portions where heat is absorbed is cooled. On the other hand, in the thermoelectric module 10, when the pair of substrates 11-1, 11-2 have different temperatures, voltage is produced by the Seebeck effect.

FIGS. 3 to 9 are perspective views schematically showing a process of manufacturing the asymmetric thermoelectric module according to the embodiment of the present invention.

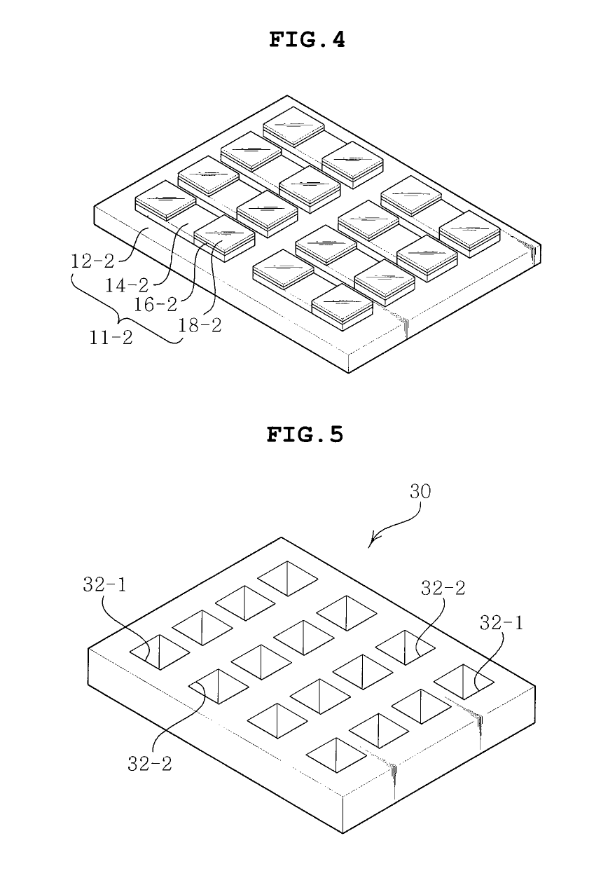

As shown in FIG. 3, a top substrate 11-1 including an insulating member 12-1 and electrodes 14-1 attached to the lower surface of the insulating member 12-1 is prepared, and as shown in FIG. 4, a bottom substrate 11-2 including an insulating member 12-2 and electrodes 14-2 attached to the upper surface of the insulating member 12-2 is prepared.

These substrates 11-1, 11-2 are configured such that a plurality of electrodes 14-1, 14-2 made of Cu or the like is joined in a predetermined pattern onto plate type insulating members 12-1, 12-2 made of Al or the like.

Also buffer layers 16-1, 16-2 are formed on the electrodes 14-1, 14-2 of the substrates 11-1, 11-2, and assistant layers 18-1, 18-2 are disposed on the buffer layers 16-1, 16-2.

The buffer layers 16-1, 16-2 and the assistant layers 18-1, 18-2 have a rectangular shape, but the shape thereof may vary depending on the design conditions required of the thermoelectric module 10, in particular, the shape of cross-section of the semiconductor elements 20-1, 20-2 to be produced.

The assistant layers 18-1, 18-2 may be manufactured by preparing a slurry or paste of a metal compound mixture, which is then subjected to batch molding or printing, drying and then final firing.

When the assistant layers 18-1, 18-2 are formed in this way, pressure firing may be carried out in an atmosphere of Ar or N₂ in order to prevent oxidation of the metal compound.

Also, the electrodes 14-1, 14-2 disposed on the insulating members 12-1, 12-2 may be formed in any pattern so long as the P-type and N-type semiconductor elements 20-1, 20-2 disposed thereto are connected in series. For example, as shown in FIG. 3, in the case of the top substrate 11-1, the electrodes at the center may be disposed side by side, and the electrodes at both edges may be disposed perpendicular to the electrodes at the center. In the case of the bottom substrate 11-2, respective electrodes 14-2 may be disposed side by side.

Subsequently, as shown in FIG. 5, a support 30 having a plurality of holes 32 formed in a predetermined pattern is prepared. In the present embodiment, a combination support 30 composed of P-type holes 32-1 and N-type holes 32-2 alternately arranged such that P-type and N-type semiconductor elements 20-1, 20-2 are formed is used. The holes 32-1, 32-2 of the combination support 30 have a predetermined diameter and height. Alternatively, a P-type support composed exclusively of holes 32-1 for forming P-type semiconductor elements 20-1 or an N-type support composed exclusively of holes 32-2 for forming N-type semiconductor elements 20-2 may be used.

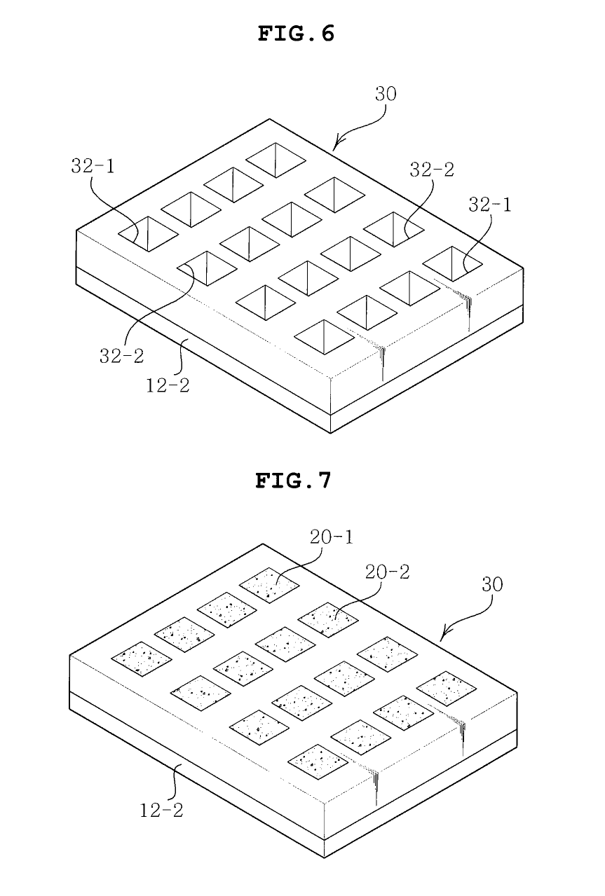

Next, as shown in FIG. 6, the support 30 is positioned on the bottom substrate 11-2. In this procedure, an additional position alignment mechanism (not shown) may be used to exactly align the position of the electrodes 14-2 of the bottom substrate 11-2 with the position of the holes 32-1, 32-2 of the support 30. In subsequent injection and/or compacting processes, the support 30 may be fixedly positioned with respect to the bottom substrate 11-2.

Next, as shown in FIG. 7, thermoelectric material powders 22-1, 22-2 and low-melting-point metal powders 24-1, 24-2 are mixed in a predetermined ratio (thermoelectric powders and about 0.25˜10 wt % of low-melting-point metal powders) thus preparing P-type and N-type semiconductor element powders 20-1, 20-2, after which the P-type and N-type semiconductor element powders 20-1, 20-2 are injected into the corresponding holes 32-1, 32-2 of the combination support 30. This injection process may be performed using an injector or blade which is not shown.

Also, after or during injection of the semiconductor element powders 20-1, 20-2 into the holes 32-1, 32-2 of the combination support 30, compacting the semiconductor element powders using an additional cylinder (not shown) may be performed.

Alternatively, such injection and/or compacting may be carried out by injecting and/or compacting only P-type semiconductor element powders using a P-type support and then injecting and/or compacting only N-type semiconductor element powders using an N-type support, instead of using the combination support 30 as above.

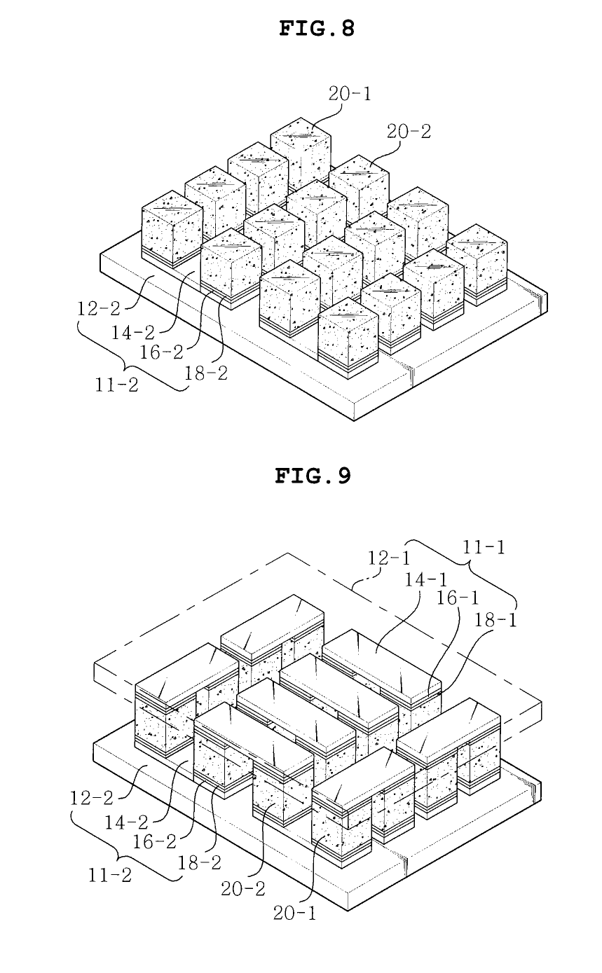

Next, the support 30 is separated from the bottom substrate 11-2. Then, as shown in FIG. 8, the semiconductor element powders 20-1, 20-2 may be maintained in for example a rectangular shape by the compacting process as above.

Subsequently, as shown in FIG. 9, the top substrate 11-1 is positioned on the other end of the semiconductor element powders 20-1, 20-2 so as to face the bottom substrate 11-2. Also in this case, an additional position control means or mechanism which is not shown may be used.

Next, as mentioned above, the intermediate product of the semiconductor element powders 20-1, 20-2 between the top substrate 11-1 and the bottom substrate 11-2 is thermally treated at a temperature which is lower than the melting point of the thermoelectric material but is higher than the melting point of the low-melting-point metal powders. If so, while the low-melting-point metal powders 24-1, 24-2 included in the semiconductor element powders 20-1, 20-2 are melted, the semiconductor element powders may be molded and simultaneously the low-melting-point metal powders 24-1, 24-2 at the ends of the semiconductor element powders 20-1, 20-2 may be fused (joined) to the top substrate 11-1 and the bottom substrate 11-2.

According to another embodiment, semiconductor element powders 20-1, 20-2 may be injected into holes 32-1, 32-2 of a support 30 disposed on the bottom substrate 11-2 and then compacted, after which, with the support 30 not being removed from the bottom substrate 11-2, thermal treatment may be performed at a temperature which is higher than the melting point of the low-melting-point metal but is lower than the melting point of the thermoelectric material in a predetermined space, so that the semiconductor element powders 20-1, 20-2 may be primarily molded and one end of the semiconductor element powders 20-1, 20-2 may be joined to the bottom substrate 11-2. Subsequently, the support 30 may be separated from the bottom substrate 11-2, and the top substrate 11-1 may be positioned on the other end of the semiconductor element powders 20-1, 20-2, after which the semiconductor element powders 20-1, 20-2 may be secondarily heated (under the same conditions as in primary heating) and thus the other end of the semiconductor element powders 20-1, 20-2 may be joined to the top substrate. The joining of the top substrate 11-1 and the other end of the semiconductor element powders may be carried out simultaneously or separately with soldering, laser welding, etc.

As described hereinbefore, the present invention provides an asymmetric thermoelectric module and a method of manufacturing the same. According to the present invention, thermoelectric performance can be improved by thermal conductivity without phonon scattering.

Also, according to the present invention, rapid thermal expansion can be alleviated, thus preventing cracking at contact points.

Also, according to the present invention, when this module operates in an acid/base atmosphere, corrosion resistance can be ensured, thus reducing changes in electrical conductivity and thermal resistance with time.

Also, according to the present invention, diffusion of semiconductor elements can be prevented and thus predetermined strength can be maintained.

Although the embodiments of the present invention have been disclosed for illustrative purposes, those skilled in the art will appreciate that a variety of different modifications, additions and substitutions are possible, without departing from the scope and spirit of the invention as disclosed in the accompanying claims. Accordingly, such modifications, additions and substitutions should also be understood as falling within the scope of the present invention.

What is claimed is:

1. An asymmetric thermoelectric module, comprising:
a plurality of first-type thermoelectric semiconductor elements having exposed surfaces at upper and lower surfaces thereof;
a plurality of second-type thermoelectric semiconductor elements arranged in matrix form so as to be disposed adjacent to the first-type thermoelectric semiconductor elements by predetermined spaces and having exposed surfaces at upper and lower surfaces thereof;
a plurality of pairs of assistant layers having different melting points and disposed on the upper and lower surfaces of the first-type thermoelectric semiconductor elements and the second-type thermoelectric semiconductor elements; and
a pair of substrates comprising a pair of insulating members and a plurality of electrodes joined in a predetermined pattern to a surface of each of the pair of insulating members and attached to the corresponding assistant layers.

2. The asymmetric thermoelectric module as set forth in claim 1, comprising a plurality of buffer layers formed on surfaces of the facing electrodes of the substrates and having areas corresponding to the first-type thermoelectric semiconductor elements and the second-type thermoelectric semiconductor elements.

3. The asymmetric thermoelectric module as set forth in claim 1, wherein one of the pair of assistant layers comprises a material having a lowest melting point selected from among thermoelectric materials that form the thermoelectric semiconductor elements, and the other thereof comprises a material having a highest melting point selected from among thermoelectric materials that form the thermoelectric semiconductor elements.

4. The asymmetric thermoelectric module as set forth in claim 1, wherein one of the pair of assistant layers is an assistant layer comprising Te, and the other thereof is an assistant layer comprising Bi.

5. The asymmetric thermoelectric module as set forth in claim 1, wherein one of the pair of assistant layers is an assistant layer comprising Co, and the other thereof is an assistant layer comprising Ti.

6. The asymmetric thermoelectric module as set forth in claim 1, wherein a thickness of each of the pair of assistant layers is 1/10˜1/100 of a thickness of the thermoelectric semiconductor elements.

7. The asymmetric thermoelectric module as set forth in claim 1, wherein the thermoelectric semiconductor elements comprise thermoelectric material powders and low-melting-point metal powders, mixed in a predetermined ratio.

8. A method of manufacturing an asymmetric thermoelectric module, comprising:
(A) joining a plurality of electrodes in a predetermined pattern to a surface of each of a pair of insulating members and forming pairs of assistant layers on the electrodes, thus preparing a pair of substrates;
(B) positioning a support having a plurality of holes on one of the pair of substrates;
(C) injecting thermoelectric semiconductor powders into the holes of the support, compacting the thermoelectric semiconductor powders, and then separating the support; and
(D) positioning the other of the pair of substrates on one of the pair of substrates having the thermoelectric semiconductor powders formed thereon, and then performing thermal treatment so that the thermoelectric semiconductor powders are joined to the pair of substrates.

9. The method as set forth in claim 8, further comprising (E) forming buffer layers on the electrodes of the pair of substrates, before forming the assistant layers in (A).

10. The method as set forth in claim 8, wherein (C) comprises:
(C-1) injecting the thermoelectric semiconductor powders into the holes of the support;
(C-2) compacting the thermoelectric semiconductor powders injected into the holes of the support; and
(C-3) separating the support from the substrate.

11. The method as set forth in claim 8, wherein one of the pair of assistant layers is an assistant layer comprising Te, and the other thereof is an assistant layer comprising Bi.

12. The method as set forth in claim 8, wherein one of the pair of assistant layers comprises at least one selected from among Co, Mo and W, and the other thereof comprises at least one selected from among Ti, Cr, Mn and Fe.

13. The method as set forth in claim 8, wherein a thickness of each of the pair of assistant layers is 1/10˜1/100 of a thickness of the thermoelectric semiconductor elements.

14. The method as set forth in claim 8, wherein the thermoelectric semiconductor elements comprise thermoelectric semiconductor powders and low-melting-point metal powders, mixed in a predetermined ratio.
